(19) United States
(12) Patent Application Publication
(10) Pub. No.: US 2016/0104853 A1
(43) Pub. Date: Apr. 14, 2016

(54) EXCITON GATING IN ORGANIC PHOTOVOLTAIC CELLS

(71) Applicant: Regents of the University of Minnesota, Minneapolis, MN (US)

(72) Inventors: Russell J. Holmes, Chanhassen, MN (US); Tyler K. Mullenbach, Maple Grove, MN (US); Stephen M. Menke, Minneapolis, MN (US)

(21) Appl. No.: 14/879,366

(22) Filed: Oct. 9, 2015

Related U.S. Application Data
(60) Provisional application No. 62/062,387, filed on Oct. 10, 2014.

(51) Int. Cl. H01L 51/42

(52) U.S. Cl. CPC H01L 51/4293

(57) ABSTRACT

An example organic photovoltaic device includes an organic electron donor region, and an organic electron acceptor region. The acceptor region forms a donor-acceptor interface with the donor region. At least one of the donor region and the acceptor region includes an exciton permeable interface. An energy transfer imbalance across the exciton permeable interface is configured to bias exciton transfer towards the donor-acceptor interface.

### CROSS REFERENCE TO RELATED APPLICATIONS

This application claims the benefit of priority under 35 U.S.C. 119(e) to U.S. Application No. 62/062,387 filed Oct. 10, 2014.

### FEDERALLY SPONSORED RESEARCH OR DEVELOPMENT

This invention was made with government support under DMR-116566, DMR-1307066 and CBET 1067681 awarded by the National Science Foundation. The government has certain rights in the invention.

### TECHNICAL FIELD

The present disclosure relates to exciton gating in organic photovoltaic cells.

### BACKGROUND

Photovoltaic cells based on organic semiconductors are attractive for their inherent compatibility with lightweight substrates and high throughput processing techniques. In order to realize efficient power conversion, the tightly bound excitons generated under optical excitation must be efficiently dissociated, and the constituent electronic charges separated and collected. The excitonic character of the excited state thus introduces a challenge into the photoconversion process, namely, how to realize dissociation and maximize exciton harvesting. In many organic photovoltaic cells (OPVs), dissociation is realized at an electron donor-acceptor (D-A) interface. Consequently, the efficiency of exciton harvesting depends strongly on the ability of the exciton to reach said interface. Straightforward exciton migration is exacerbated by a short exciton diffusion length (L_{D}) relative to the optical absorption length in most organic semiconductors.

Much effort in the optimization of OPV architecture reflects a fundamental challenge in solid-state physics, namely, how to direct the motion of the neutral exciton. In inorganic semiconductors, excitonic phenomena are often not considered at room temperature due to their low binding energy and straightforward dissociation via thermal energy. When present, the large radius of the Wannier-Mott-type excitons of these systems permits some degree of spatial manipulation via applied electric fields. In organic semiconductors, the localized Frenkel-type exciton is strongly bound, often making manipulation with an applied field more difficult.

### SUMMARY

The ability to direct exciton transport using a consistent scheme for biasing exciton motion would have broad application in a variety of optoelectronic devices, of particular note for photoconversion and exciton harvesting in an OPV.

Directed exciton transport may be achieved with the incorporation of exciton permeable interfaces. These interfaces introduce a symmetry-breaking imbalance in exciton energy transfer rates, leading to super-diffusive motion. Accordingly, among other benefits, exciton permeable interfaces may enable enhanced exciton harvesting in organic photovoltaic cells (OPVs). This disclosure demonstrates directed exciton transport in both dilute donor and energy-cascade OPVs where judicious optimization of the interface allows super-diffusive motion to be exploited for enhanced exciton transport. Generalized systems incorporating multiple exciton permeable interfaces are also described, demonstrating the ability to overcome the diffusive limit by directing exciton motion.

In general, in an aspect, an organic photovoltaic device includes an organic electron donor region, and an organic electron acceptor region. The acceptor region forms a donor-acceptor interface with the donor region. At least one of the donor region and the acceptor region includes an exciton permeable interface. An energy transfer imbalance across the exciton permeable interface is configured to bias exciton transfer towards the donor-acceptor interface.

Implementations of this aspect may include one or more of the following features.

In some implementations, the energy transfer imbalance can be due to a difference in concentration of a first material across the exciton permeable interface.

At least one of the donor region and the acceptor region can include a first organic layer including a first concentration of the first material, and a second organic layer include a second concentration of the first material. The first organic layer can be disposed between the second organic layer and the donor-acceptor interface. The first concentration can be greater than the second concentration. The exciton permeable interface can be an interface between the first organic layer and the second organic layer.

In some implementations, the first concentration can be 100%. In some implementations, the first concentration can be less than 100%.

In some implementations, the energy transfer imbalance can be due to a difference in molecular ordering across the exciton permeable interface.

In some implementations, the energy transfer imbalance can be due to a difference in photoluminescence efficiency across the exciton permeable interface.

In some implementations, the energy transfer imbalance can be due to a difference in index of refraction across the exciton permeable interface.

In some implementations, the energy transfer imbalance can be due to a difference in molecular orbital energy levels across the exciton permeable interface.

In some implementations, the energy transfer imbalance can be due to a difference in spectral overlap integral across the exciton permeable interface.

In some implementations, the acceptor region can include an optically absorbing material.

In some implementations, at least one of the donor region and the acceptor region can further include a plurality of exciton permeable interfaces. An energy transfer imbalance across each exciton permeable interface can be configured to bias exciton transfer towards the donor-acceptor interface. At least one of the donor region and the acceptor layer can include further include a plurality of organic layers. Each exciton permeable interface can be an interface between adjacent organic layers.

In some implementations, an energy transfer imbalance across the plurality of layers can be configured to bias exciton transfer towards the donor-acceptor interface.

In some implementations, each organic layer can have a respective concentration of a material such that the material concentration varies monotonically across the plurality of organic layers.

In some implementations, each organic layer can have a respective concentration of a material such that the material concentration varies continuously across the plurality of organic layers.

In some implementations, at least one organic layer can have a respective concentration of material that varies across that organic layer.

In some implementations, the organic photovoltaic device can further include one or more additional organic electron donor regions and one or more additional organic acceptor region. The additional electron donor regions and additional acceptor regions can form one or more additional donor-acceptor interfaces. At least one of the additional donor regions and acceptor regions can include an additional exciton permeable interface. An energy transfer imbalance across the additional exciton permeable interface can be configured to bias exciton transfer towards at least one of the additional donor-acceptor interfaces.

In some implementations, the energy transfer imbalance can be due to a difference in exciton radiative decay rate across the exciton permeable interface.

The details of one or more implementations are set forth in the accompanying drawings and the description below. Other features and advantages will be apparent from the description, the drawings, and the claims.

### BRIEF DESCRIPTION OF THE DRAWINGS

FIG. 1 is a diagram of an example OPV device.

FIG. 2A is a diagram of an example exciton permeable interface.

FIG. 2B is a chart of normalized exciton density for the schematic system as a function of imbalance at the permeable interface.

FIG. 3A is a diagram of the layer structure for energy-cascade OPVs. Also shown is the molecular structure for boron subnaphthalocyanine chloride (SubNc).

FIG. 3B is a chart of current-density-voltage characteristics for an example champion cell.

FIG. 3C is a chart of simulated and measured η_{EQE} at wavelengths corresponding to regions of predominant absorption for both boron subphthalocyanine chloride (SubPc) and SubNc, respectively.

FIG. 3D is a chart of simulated η_{D} for both SubPc and SubNc for the as measured OPV as well as an artificial OPV that has no imbalance at the permeable interface.

FIG. 4A is a diagram of the layer structure for dilute donor OPVs where directed exciton transport results from an imbalance in molecular site density and energy transfer rates resulting from increased intermolecular separation. Also shown are the molecular structures for SubPc and p-bis(triphenylsilyl)benzene (UGH2).

FIG. 4B is a chart of simulated and measured η_{EQE} for dilute donor OPVs as well as the corresponding η_{A} and η_{D}.

FIG. 4C is a chart of donor η_{D} as a function of imbalance at the exciton permeable interface.

FIG. 5A is a schematic describing an example model experiment where the exciton transport is characterized across a 16-nm structure containing a variable number of exciton permeable interfaces.

FIG. 5B shows the mean-squared displacement for excitons traversing the structure described with respect to FIG. 5A versus time as a function of the number of exciton permeable interfaces present in the structure.

FIG. 5C shows the derivative of the mean-squared displacement (FIG. 5B) for an example 16-nm structure with a varying number of exciton permeable interfaces.

FIGS. 6A-D are histograms representing the recorded locations of exciton decay within the layer as well as the η_{T} for the various structures shown in FIG. 5A. Also shown is the variation in L_{D} across the layer.

FIG. 6E is a chart of transport efficiency (η_{T}) as a function of increasing number of interfaces.

FIG. 6F is a chart of average transit time for excitons that traverse the entire structure shown in FIG. 5A.

FIG. 7 is a diagram of bulk and interfacial hopping rates used to simulate energy-cascade.

FIG. 8 is a diagram of layer structures for quenched and unquenched samples for photoluminescence quenching experiments.

FIG. 9 is a chart of measured and simulated photoluminescence (PL) ratios as a function of interlayer concentration for the structures presented in FIG. 8. Also shown is the tabulated exciton diffusion efficiency as a function of interlayer concentration.

### DETAILED DESCRIPTION

This disclosure describes implementations for directed energy transfer and enhanced exciton diffusion in organic semiconductors. In particular, this disclosure demonstrates that while gains in exciton harvesting are possible with enhanced bulk L_{D}, a more effective approach can be achieved by introducing exciton permeable interfaces that intentionally bias energy transfer and exciton transport toward the donor-acceptor (D-A) interface. Such passive exciton gates break the symmetry associated with normal diffusion transitioning to a super-diffusive regime. In the super-diffusive regime, excitons realize large diffusion efficiencies without the need to increase the area of the dissociating interface.

As described herein, exciton permeable interfaces between material layers act as a mechanism for enhanced diffusion. Notably, an imbalance in energy transfer rates across the interface imparts directed exciton transfer towards the donor-acceptor interface, also contributing to an increase in exciton diffusion efficiency (η_{D}) for the device.

This effect of these interfaces can be quite general. To understand how this imbalance is derived, consider the following equation where k_{T} is the total rate of exciton hopping, k_{A} is the hopping rate to an individual hopping site from a set of all possible hopping sites, A, and d is the distance to that hopping site. Exemplary materials properties a, b, c, signify that the hopping rate is material dependent and can vary depending on the mechanism for exciton transport. Example material properties include molecular ordering, radiative decay rate of the exciton, index of refraction, molecular orbital energy levels (or energy gap), and exciton transfer integrals. Importantly, changes in these rates, along with d, at an interface create direction-dependent imbalances in the total hopping rate.

k_{T}=Σk_{A}(d,a,b,c)

Although k_{T} is shown above as depending on three example parameters a, b, and c, the actual number of parameters may vary depending on the mechanism for exciton transport.

When an exciton is in the middle of a layer, the individual hopping rates are the same in all directions and the exciton transport in the film is said to be diffusive. At an interface however, there can be an imbalance in individual hopping rates where, for instance, the hopping rate into the next layer is larger than the hopping rate to remain in the current layer. Such a situation results in anomalous diffusion.

In the case of the dilute donor OPVs containing a dilute organic donor layer directly adjacent to a neat organic layer, this imbalance is achieved through a discontinuity in molecular site density, e.g., an exciton in the dilute layer at the interface experiences more possible destination sites in the more concentrated neat layer than in the dilute layer. As such, there will be a larger probability for excitons to move into the more concentrated layer resulting in directed exciton motion.

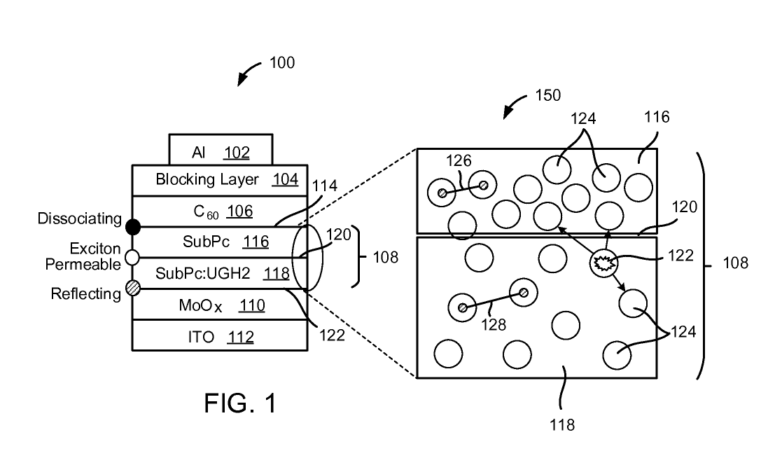

FIG. 1 is a schematic that illustrates an example OPV device 100. The device 100 includes a top electrode 102 (e.g., Al), a blocking layer 104 (e.g., bathocuproine—BCP, TiO₂), an acceptor region 106 (e.g., C₆₀), donor region 108, an interlayer/hole transport layer 110 (e.g., MoO_{X}) and a bottom electrode 112 (e.g., indium tin oxide—ITO). The donor region 108 forms a donor-acceptor interface 114 with the acceptor region 106 at the location where the donor region 108 comes into contact with the acceptor region 106 (i.e., the dissociating interface). In some implementations, the donor region 108 can include two or more donor layers (e.g., a neat donor layer 116 composed of boron subphthalocyanine chloride—SubPc—and a dilute donor layer 118 composed of SubPc diluted in p-bis(triphenylsilyl)benzene—SubPc:UGH2), and an exciton permeable interface 101 between one or more pairs of adjacent donor layers. The OPV device 100 also includes a reflecting interface 122 where the interlayer/hole transport layer 110 comes into contact with the bottom electrode 112 (e.g., as shown in FIG. 1) In some cases, the OPV device 100 can include a quenching interface instead of a reflecting interface 122.

Although an example OPV device 100 is show in FIG. 1, this is merely an illustrative example. Other configurations are possible, depending on the implementation. For example, in some cases, an OPV device can include an acceptor region 106 having including multiple acceptor layers and an exciton permeable interface between one or more pairs of adjacent acceptor layers. Further, in some cases, an OPV device 100 can include multiple donor regions and/or multiple acceptor regions. Further still, an OPV device 100 can include multiple exciton permeable interfaces formed within one or more donor regions and/or acceptor regions. For example, a donor region can include three or more dilute donor layers (or two or more dilute donor layers and a neat donor layer), each of which is formed by diluting a different concentration of guest material in a wider band gap host material. Each interface between adjacent dilute donor layers (and between a dilute donor layer and a neat donor layer) may form an exciton permeable interface as disclosed herein. Likewise, an acceptor region can include three or more dilute acceptor layers (or two or more dilute acceptor layers and a neat acceptor layer), where the interface between adjacent dilute acceptor layers (and between a dilute acceptor layer and a neat acceptor layer) may form an exciton permeable interface as disclosed herein.

The inset 150 shows a close up of the exciton permeable interface 120 between two different donor layers 116 and 118 of the donor region 108. An exciton 122 in the dilute donor layer 118 at the exciton permeable interface 120 experiences a greater number of possible acceptor sites 124 in the more concentrated donor layer 116 than in the dilute donor layer 118. Further, the distances between acceptor sites 124 in the more concentrated donor layer 116 (e.g., distance 126) are, on average, shorter than the distances between acceptor sites 124 in the dilute donor layer 118 (e.g., distance 128). As such, there will be a larger probability for excitons to move into the more concentrated donor layer 116, resulting in directed exciton motion.

Although concentration imbalance is one mechanism of providing an imbalance in energy transfer across an interface 120, other mechanisms are also possible. For example, as an alternative or in addition to concentration imbalances between layers, an imbalance in energy transfer across an interface may be achieved by varying other molecular parameters that affect the above equation (e.g., a, b, c). The following equation describes the hopping rate of excitons that undergo Förster energy transfer, connecting the hopping rate to molecular parameters. Here, τ is the exciton lifetime, η_{PL} is the photoluminescence efficiency, κ is the dipole orientation factor, n is the index of refraction, λ is the wavelength, F_{D} is the normalized fluorescence, and σ_{A} is the molecular absorption cross-section.

$${k}_{F} = \frac{1}{τ {d}^{6}} ( \frac{9 {η}_{PL} {κ}^{2}}{128 {π}^{5} {n}^{4}} \int {λ}^{4} {F}_{D} ( λ ) {σ}_{A} ( λ ) d λ )$$

In the context of Förster energy transfer, a list of parameters that could possibly be varied can include:
1. Molecular ordering—this alters the dipole orientation factor, K, across the interface. κ² can vary between 0 and 4. While not solely capable of injecting super-diffusive motion, optimized dipole orientation may be used to enhance the imbalance at the interface. In order to create a permeable interface that biases transport toward the donor-acceptor interface, the degree of dipole ordering (as referenced to κ²) should be larger in the material closer to the donor-acceptor interface than in the material farther from the donor-acceptor interface. This will ensure a favorable increase in the rate of energy transfer toward the donor-acceptor interface.
2. Radiative decay rate of the exciton (k_{R})—increases in this property, directly increase the rate of exciton hopping. Typically, differences in k_{R} manifest in the photoluminescence efficiency (η_{PL}) are a varied by changing the chemical nature of the excited state via synthetic design. Values of k_{R} typically vary between 10⁹ s⁻¹ and 10⁶ s⁻¹ and values of the η_{PL} vary between 0 and 100%. In order to create a permeable interface that biases transport toward the donor-acceptor interface, the difference in k_{R} between layers should be such that a greater k_{R} is present farther from the donor-acceptor interface. This will ensure that the rate of transport across an interface toward the donor-acceptor interface is larger than the corresponding reverse rate away from the donor-acceptor interface.
3. Index of refraction—this property also directly affects the rate of exciton hopping via Förster energy transfer where lower values of n are ideal. Typical values of n for organic semiconductors vary generally between 1 and 3. In order to create a permeable interface that biases transport toward the donor-acceptor interface, a smaller value of the index is preferred in the layer closer to the donor-acceptor interface than in the material farther from the donor-acceptor interface.
4. Molecular orbital energy levels (or energy gap)—variations in the energy levels, associated with different molecular species across the interface, directly affect the fluorescence and absorption cross-section. Of the described properties, variation of the energy-gap has the greatest ability to achieve large imbalances since it is possible to realize nearly no exciton hopping in a given direction across an interface. In order to create a permeable interface that biases transport toward the donor-acceptor interface, the energy gap should decrease in the direction of the donor-acceptor interface.
5. Spectral overlap integrals—Differences in energy transfer coming from variations in the spectral overlap integral ∫λ⁴F_{D} (λ) σ_{A}(λ) dλ across the interface. In order to create a permeable interface that biases transport toward the donor-acceptor interface, the value of this integral should be larger when calculated in the direction of transport toward the donor-acceptor interface. If all other factors are equal, this could arise if the absorption cross-section of the layer closer to the donor-acceptor material is larger than the absorption cross-section of the layer farther from the donor-acceptor interface.
6. Exciton transfer integrals—Differences in energy transfer coming from non-Förster type processes.

While any or all these parameters can be used to create an imbalance, in some cases, dilution might be the most easily realized and most amenable to creating very large and tunable imbalances in exciton hopping. To demonstrate the power of this effect, as described below, we performed some simulations where we monitor the ability for an exciton to traverse a 16-nm thick layer and vary the number of permeable interfaces. We hold the bulk transport (L_{D}) constant between the simulations to only capture the effect of the interfaces. In some implementations, we can increase the transport efficiency (η_{T}) and reduce the average transit time by moving from a bilayer case with one interface to an effectively graded case with nominally 15 interfaces.

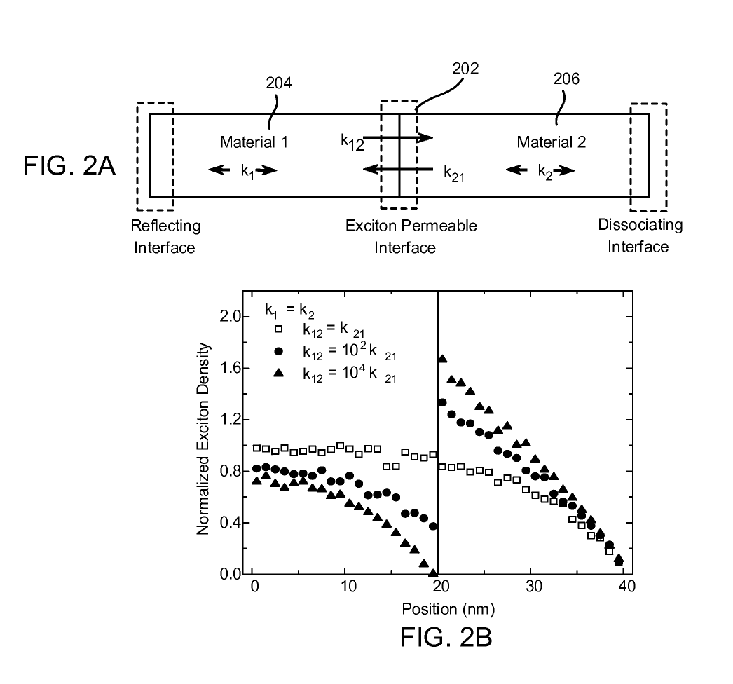

In an example configuration, a passive exciton gate may be formed at the interface between two materials (e.g., as shown in FIG. 2A) where there exists an imbalance in the forward and reverse exciton transfer rates. Exciton permeable interfaces are characterized by non-destructive flux between two materials. The imbalance at the interface is defined as k₁₂/k₂₁. As an example, one or more interfaces 202 can be formed in an electron donor region of a device (e.g., a continuous region of one or more layers of donor material) and/or in an electron acceptor region of a device (e.g., a continuous region of one or more layers of acceptor material). This imbalance can arise from a number of different material or device configurations. For example, Material 1 (204) in FIG. 2A may be a donor material with a larger energy gap than Material 2 (206). A pair of donor layers satisfying this criterion is often a critical component of an energy-cascade OPV. In such a structure, an exciton to the left of the interface has a nonzero probability of moving either left or right, while an exciton on the right of the interface may only move to the right due to conservation of energy. Thus, an interface of this type relies on an energetic asymmetry to realize the required rate imbalance. Although the use of electronic donor materials is described above, this is merely an illustrative example. In practice, this phenomenon is not limited only to the use of electron donor materials. In some cases, the same behavior could also be observed using electron accepting materials.

In a second example configuration, an interface between dilute and neat layers of a single molecular species can lead to a similar asymmetry in rates. One or more interfaces can be formed in a donor region of a device (e.g., a continuous region of one or more layers of donor material) and/or in an acceptor region of a device (e.g., a continuous region of one or more layers of acceptor material). To illustrate, referring to the schematic of FIG. 2A, Material 1 (204) can be a layer of donor material (i.e., a guest donor material) diluted into a wide energy gap matrix (i.e., a host material) while Material 2 (206) can be a neat layer of the same donor material (i.e., the guest donor material in Material 1). In this dilute donor configuration, there is no energetic asymmetry as the exciton is confined to the donor species on both sides of the interface 202. There is however, a difference in the molecular site density between the dilute and neat materials, creating the required asymmetry. For an exciton immediately to the left of this interface 202, dilution reduces the number of molecular destination sites in the dilute layer relative to the neat layer, and the same holds for excitons on the right side of the interface. Since the rate of hopping is proportional to the number of sites, the site imbalance creates an asymmetry in hopping rates.

Although the use of electronic donor materials is described above, this is merely an illustrative example. In practice, this phenomenon is not limited only to the use of electron donor materials. In some cases, the same behavior could also be observed using dilute electron accepting materials.

Example guest donor materials include organic semiconductors such as phthalocyanines, subphthalocyanines, naphthalocyanines, rubrenes, indenes, linear acenes, metallocenes, squaraines, thiophenes, polythiophenes or polyphenylene-vinylenes among others.

Example wide energy gap host include organic semiconductors such as, for example, phenanthrolines, imidazoles, amines, carbazoles, triarylsilanes, polystyrenes, polyvinylalcohols, polyvinylcarbazoles, among others. Host materials are acceptable for use in either diluted donor layers or diluted acceptor layers, so long as the guest material's highest occupied molecular orbital (HOMO) and lowest unoccupied molecular orbital (LUMO) levels are arranged with respect to the HOMO and LUMO levels of the host material so as to confine exciton diffusion to the guest material as described above. Consequently, for narrower gap host materials, similarly narrow gap hosts may also be used, as is the case with SubPc and boron subnaphthalocyanine chloride (SubNc) as host and guest.

In diluting acceptor materials, options could include, for example, fullerenes (e.g., C₆₀ or C₇₀), naphthalene derivatives, bathophenanthroline (Bphen), perylene derivatives, such as 3,4,9,10-perylenetetracarboxylic-bis-benzimidazole (PTCBI) or perylenetetracarboxylic dianhydride (PTCDA), fluorinated electron donors, or polymeric fullerene derivatives (PCBM).

In some implementations, the wide energy gap matrix material may also be absorbing and hence can serve as an additional contribution to the photocurrent. For example, the wide energy gap matrix material can be optically absorbing (e.g., such that it absorbs incident visible light). This absorbed energy in turn contributes to the device's photocurrent. This can be beneficial, for example, as it can enhance the efficiency of the device, while also maintaining the directed energy transfer and enhanced exciton diffusion properties provided by the exciton permeable interfaces.

Here, we present results demonstrating exciton gating and enhanced exciton transport for architectures exploiting both the energetic and site density asymmetries discussed above. In order to isolate the role of the interface in determining the overall efficiency of exciton transport, a Kinetic Monte Carlo (KMC) formalism was developed to solve the 1-D exciton diffusion equation across exciton permeable interfaces. The advantage of this stochastic solution is that the boundary condition for the permeable interface did not need to be known a priori, and was, instead, constructed by identifying the imbalance in exciton energy transfer rates at the interface. Other device related boundary conditions, such as exciton reflecting and dissociating, may also be easily incorporated as appropriate. Care was taken to ensure that the KMC solutions agree with analytical solutions for cases without permeable interfaces.

FIG. 2B demonstrates an example of the drastic effect that an imbalance in energy transfer rates can impart on the steady state exciton density profile in a model OPV multilayer system. Here, k₁₂ and k₂₁ are the energy transfer rates to Material 2 and Material 1, respectively. When the rates are equal, no imbalance is present and the conventional, continuous exciton density is retained. The presence of a rate imbalance, however, leads to a steady-state discontinuity in the exciton density at the permeable interface. The discontinuity reflects a depletion and pile-up of excitons, with a net movement towards the side of the interface to which energy transfer is favored. In this model system, the imbalance at the interface is beneficial for exciton motion rightwards (e.g., as shown in FIG. 2B), thereby also increasing the flux of excitons toward the dissociating interface adjacent to Material 2. Thus, the increasing imbalance in energy transfer leads directly to a discontinuity in the exciton density, characterized by the depletion and pile-up of excitons on the side of the interface to which energy transfer is favored.

As discussed, energy-cascade OPVs derive an imbalance in energy transfer from differences in energy gap. In such a configuration, downhill and sometimes long-range energy transfer can take place from a larger energy-gap donor to a lower energy-gap donor as is the case for boron subphthalocyanine chloride (SubPc, E_{g}=2.0 eV) to boron subnapthalocyanine chloride (SubNc, E_{g}=1.8 eV). Förster-type energy transfer from SubPc to SubNc is often favorable due to their complementary photoluminescence and absorption spectra. Predictions for the Förster radius (R₀) from SubPc to SubNc yielded R₀=2.1 nm, whereas the reverse transfer was comparatively improbable with R₀˜0 nm. Therefore, a perfect (or otherwise acceptable) imbalance was achieved leading to enhanced exciton diffusion efficiency (η_{D}) in both donor layers.

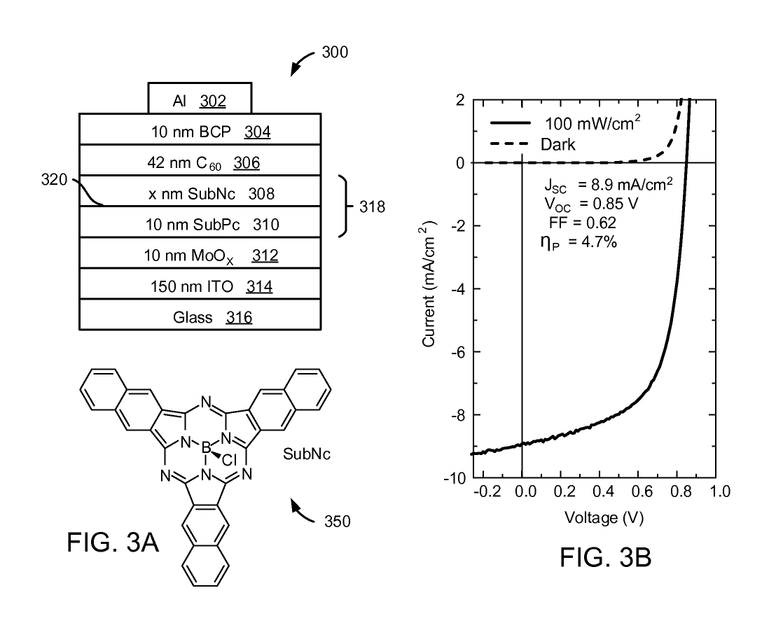

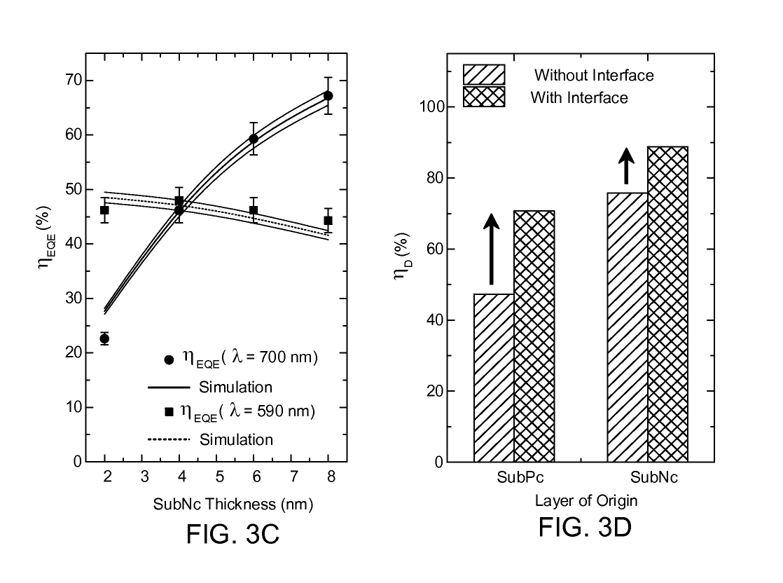

In an example implementation, energy-cascade OPVs were fabricated according to the layer structure 300 in FIG. 3A where the total donor layer 318 (e.g., a continuous donor region) includes a 10-nm-thick layer of SubPc 310 followed by a variable thickness layer of SubNc 308 (also shown is the molecular structure for SubNc 350), forming a exciton permeable interface 320 between them. In this example, a 42-nm-thick C₆₀ acceptor layer 306 was used followed by a 10-nm-thick bathocuproine (BCP) exciton blocking layer 304 and a 100-nm-thick Al cathode 302. Further, an 10-nm-thick layer of MoOₓ 312 was used as an interlayer/hole transport layer, followed by a 150-nm-thick ITO layer 314 as a bottom electrode, followed up by a layer of glass 316. In this configuration, conservation of energy dictated that excitons could only transfer from boron subphthalocyanine chloride (SubPc) to boron subnaphthalocyanine chloride (SubNc) across the exciton permeable interface 320, and not the reverse. Measurements of the power conversion efficiency (η_{P}) revealed that these example devices were quite efficient with ↓_{P}=(4.4±0.2)% when incorporating a 6-nm-thick SubNc layer. The current-density-voltage characteristics of the example champion cell are shown in FIG. 3B (incorporating a 6-nm-thick layer of SubNc) measured at 100 mW/cm2 AM1.5 G solar illumination. For comparison, the η_{P} for single, neat donor planar heterojunction OPVs paired with a C₆₀ acceptor based on SubPc and SubNc were η_{P}=3.3% and η_{P}=2.4%, respectively.

The KMC model for exciton diffusion in cascade structures incorporating exciton permeable interfaces allowed for the accurate prediction of the external quantum efficiency (η_{EQE}). As an example, the η_{EQE} was modeled for SubPc and SubNc at λ=590 nm and 700 nm, respectively, corresponding to regions of predominant absorption for each material, respectively (e.g., as shown in FIG. 3C). The KMC model accurately reproduced the experimentally obtained η_{EQE} with L_{D}=15 nm for SubNc and the previously measured value of L_{D}=10.7 nm for SubPc. An additional, thickness independent loss term of 0.75 was incorporated for excitons generated in SubPc, accounting for additional loss pathways which may include exciton quenching at the MoOₓ anode buffer layer. To directly investigate the effect of the exciton permeable interface on η_{D} in this energy-cascade structure, η_{D} was separately simulated for each donor layer. Only excitons generated in SubPc will contribute to the η_{D}^{SubPc}, with the same being true for excitons generated on SubNc and the η_{D}^{SubNc}. Furthermore, the separate values of η_{D} were simulated for the actual device with a rate imbalance at the interface as well as for an artificial device where no imbalance is present. In this context, the hopping rate for each layer in the artificial device was held constant, and the exciton lifetimes were adjusted to reflect the proper bulk L_{D} (see Supplementary Information). As can be seen from FIG. 3D, in an example implementation, the addition of the interface increased the diffusion efficiency for the SubPc and SubNc layers by 50% and 20%, respectively. The increase in the η_{D}^{SubPc} was a result of directed energy transfer to the SubNc layer at the exciton permeable interface. Since there could be no reverse energy transfer from SubNc to SubPc, excitons that were generated in the SubNc layer experienced effective reflection at the permeable interface, thereby also increasing η_{D}^{SubNc} Such drastic effects on η_{D}, and ultimately device photocurrent, often could only be quantified by correctly modeling the imbalance in energy transfer at the exciton permeable interface.

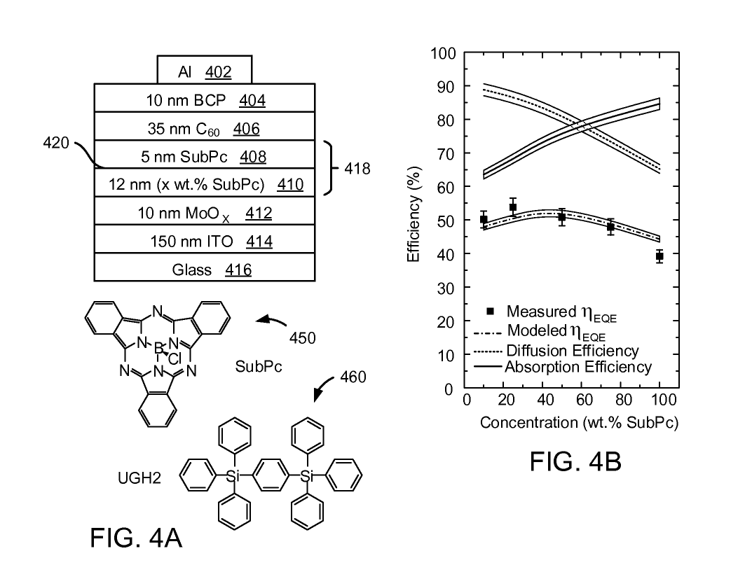

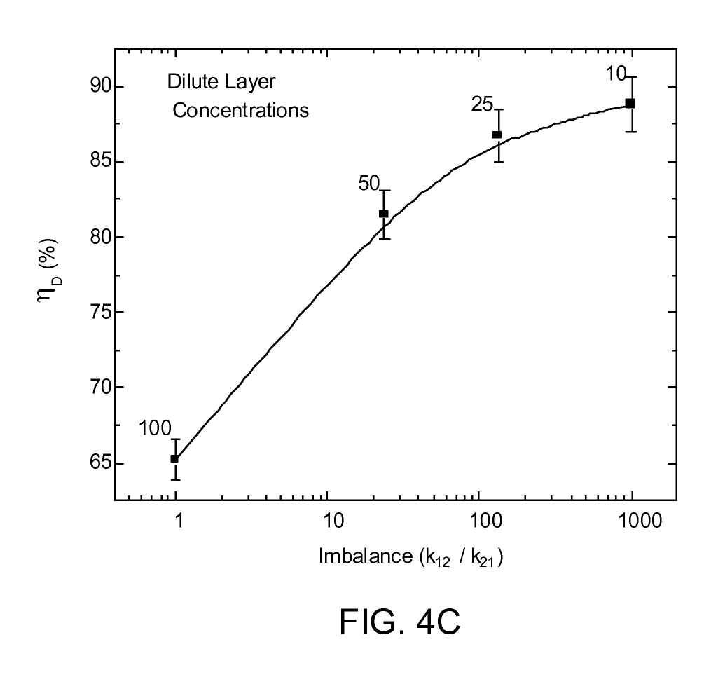

The interface between dilute and neat layers of donor material may also form an exciton permeable interface due to an asymmetry in transfer rates. In some cases, such dilute donor OPVs have shown enhanced η_{P} relative to undiluted control devices. In these devices, dilute layers of the archetypical electron donating molecule SubPc (the molecular structure for SubPc 450 is shown in FIG. 4A) dispersed in the wider energy-gap host material p-bis(triphenylsilyl)benzene (UGH2) (the molecular structure for UGH2 460 is shown in FIG. 4A) showed a 50% increase in the L_{D} of SubPc owing to optimized Förster energy transfer and intermolecular interaction. The increase in bulk L_{D} led to an enhancement in η_{D} when incorporated as part of a multilayer donor structure (e.g., as shown FIG. 4A).

In an example implementation, OPVs 400 were fabricated according to the layer structure 400 in FIG. 4A where the total donor layer 418 (e.g., a continuous donor region) includes a 5-nm-thick layer of neat SubPc 408 followed by a 12-nm-thick dilute layer of variable concentration SubPc 410 (also shown is the molecular structure for SubPc 450). In this example, a 35-nm-thick C₆₀ acceptor layer 406 was used followed by a 10-nm-thick bathocuproine (BCP) exciton blocking layer 404 and a Al cathode 402. Further, an 10-nm-thick layer of MoO₃ 412 was used as an interlayer/hole transport layer, followed by a 150-nm-thick ITO layer 414 as a bottom electrode, followed up by a layer of glass 416. Notably, in some implementations, an exciton permeable interface 420 exists between the 12-nm-thick dilute layer of variable concentration SubPc 410 and the 5-nm-thick layer of neat SubPc 408. The enhancement in η_{D} for these structures was, consequently, a combination of both bulk diffusion and interface effects. In order to model exciton migration in these devices, proper consideration of energy transfer at the permeable interface 420 is often critical. In addition to the imbalance in molecular site density, the concentration dependence of the self Förster radius (self-R₀) on dilution imparts further imbalance. An example of these contributions are pictured schematically in the inset of FIG. 4C. Photoluminescence quenching experiments and complementary simulations revealed that, in fact, the η_{D} is optimized when the interlayer includes undiluted SubPc (see Supplementary Information). This counterintuitive result contrasts the notion that exciton harvesting is optimized by incorporating active materials with the longest L_{D} and confirmed that the interface plays a critical role in driving excitons toward the D-A interface. This result provided a new axis for device design.

FIG. 4B shows an example of the measured η_{EQE} at a wavelength λ=590 nm, corresponding to predominantly SubPc absorption. A transfer matrix formalism was employed to model the incident optical field responsible for photon absorption and exciton generation. Simulated η_{EQE}, absorption efficiency (η_{A}), and η_{D} are shown as a function of dilute layer concentration. Excellent agreement with experiment was found when an additional, concentration independent loss term equal to 0.85 was included.

Similar to the energy-cascade OPVs these additional losses were expected and may reflect exciton quenching at the MoOₓ anode buffer layer and non-unity collection efficiency. Interestingly, η_{D} increased continuously upon dilution. FIG. 4C displays an example of the total donor η_{D} as a function of imbalance, which confirms the dependence of η_{D} on the degree of imbalance at the permeable interface, Here, dilution was capable of achieving very large imbalances (e.g., k₁₂/k₂₁˜100-1,000) in energy transfer, driving η_{D} to near unity. This was achieved without resorting to corrugated interface morphology or a BHJ architecture where the large D-A interface area circumvents diffusion altogether. This imbalance was also achieved for a flat energetic landscape that, in principle, created no significant asymmetry for charge transport.

As described herein, for permeable interfaces formed between dilute and neat layers of material, the rate imbalance arises from an imbalance in molecular site density. While the aforementioned implementations uses UGH2 as an optically transparent host material, additional photocurrent can be generated if the host material is also optical absorbing, while still having an energy gap that is larger than the guest material. In this way, excitons generated on both the host and guest materials experience the permeable gating interface.

For example, SubNc can used as a guest material to integrate with a photoactive host of SubPc. When SubNc is diluted in SubPc, two donor exciton harvesting pathways exist in parallel. Similar to the case of dilute SubPc, excitons generated on SubNc diffuse along a pathway from SubNc molecules toward the donor-acceptor interface. The difference in energy-gap between SubNc and SubPc is much larger than the ambient thermal energy (e.g., approximately 25 meV). Thus, excitons generated on SubNc do not energy transfer to SubPc. In this way, SubPc acts analogously to UGH2 in the aforementioned example. A second pathway is also present for excitons that originate on SubPc; efficient Förster energy transfer from SubPc to SubNc occurs rapidly, and excitons may follow the same route to the interface as those originally generated on SubNc.

Overall, in this example, photogenerated excitons are quickly confined to molecules of SubNc, followed by short range exciton energy transfer toward the donor-acceptor interface where excitons are dissociated. Here, the host-guest donor layer is distinct from composite donor layers formed from multilayer stacks, as the photogenerated charges remain solely on the guest species (SubNc) during transport towards the anode.

Example systems incorporating a single permeable interface are described above. However, implementations also can include donor regions and/or acceptor regions having multiple exciton permeable interfaces. For example, a donor region can include three or more dilute donor layers (or two or more dilute donor layers and a neat donor layer), each of which is formed by diluting a different concentration of guest material in a wider band gap host material. Each interface between adjacent dilute donor layers (and between a dilute donor layer and a neat donor layer) may form an exciton permeable interface as disclosed herein. Likewise, an acceptor region can include three or more dilute acceptor layers (or two or more dilute acceptor layers and a neat acceptor layer), where the interface between adjacent dilute acceptor layers (and between a dilute acceptor layer and a neat acceptor layer) may form an exciton permeable interface as disclosed herein.

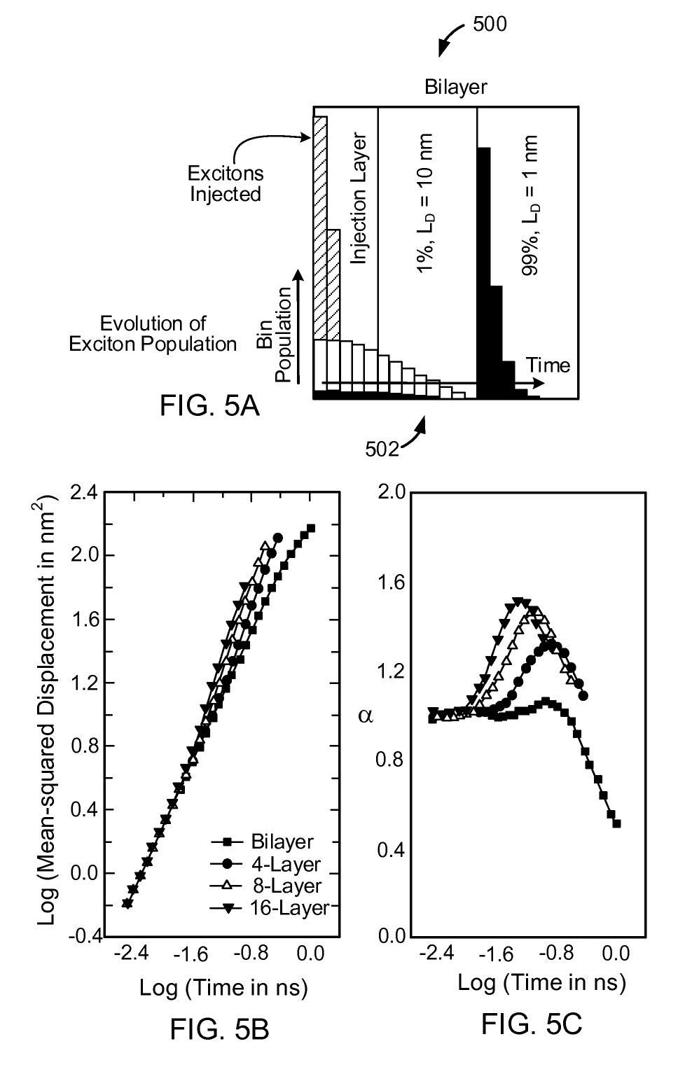

For instance, in some cases, inspection of the mean-squared displacement as a function of time can elucidate the connection between the number of permeable interfaces and the degree of anomalous diffusion. As an example, a generic system 500 having 16 1-nm-thick bins 502 was modeled, where the imbalance was derived from differences in molecular concentration. The first interface 504 was introduced by discretizing the system into two layers, one representing a very dilute layer (e.g. 1 wt. %) with L_{D}=10 nm (506) and one representing a nearly undiluted layer (e.g. 99 wt. %) with L_{D}=1 nm (508), depicted schematically in FIG. 5A. Rates were extracted from L_{D} with a lifetime of τ=1 ns. A simple molecular site density rationale was used for quantifying the imbalance in energy transfer at the interface(s). To inspect the mean-squared displacement versus time, a large population of excitons were injected through a 5-nm-thick layer 510 of the most dilute layer into the multiple interface system. The simulation was ended when the first excitons reached the opposite side of the structure. The system was further discretized into 4, 8, and 16 layers containing 3, 7, and 15 exciton permeable interfaces, respectively. A linear interpolation was used to determine the specific rates of energy transfer and relevant molecular concentrations for each layer. For example, the 4-layer system would contain layers with concentrations of 1, 34, 67, and 100 wt. % with corresponding L_{D} of 10, 8.2, 5.8, and 1 nm, respectively.

FIG. 5B shows the mean-squared displacement versus time for the various multilayer structures according to the above example. At short times, the structures behaved nearly identically. This is consistent since they all contained an identical, 5-nm-thick injection layer whereby the excitons were all sampling an identical, diffusive environment at very short times. However, when the first excitons reached the permeable interface 10-30 ps after injection, the mean-squared displacement began increasing faster, especially for the systems with a larger number of permeable interfaces. In fact, regions of the plot with slopes greater than unity indicated super-diffusive behavior. To verify, FIG. 5C displays the derivative of the FIG. 5B, where a, the slope, is defined from [symbol] x² [symbol] =βt^{α}. Values of α>1 and α<1 signify super- and sub-diffusive motion, respectively. The structures with the greatest number of permeable interfaces showed the largest degree of super-diffusive motion, with a reaching a peak value of α˜1.5. Furthermore, the peak in a occurred at increasingly shorter times as the number of permeable interfaces was increased.

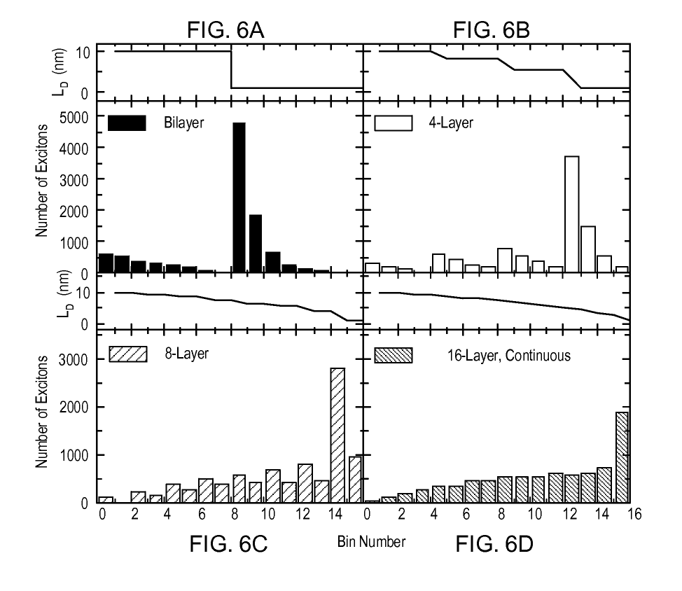

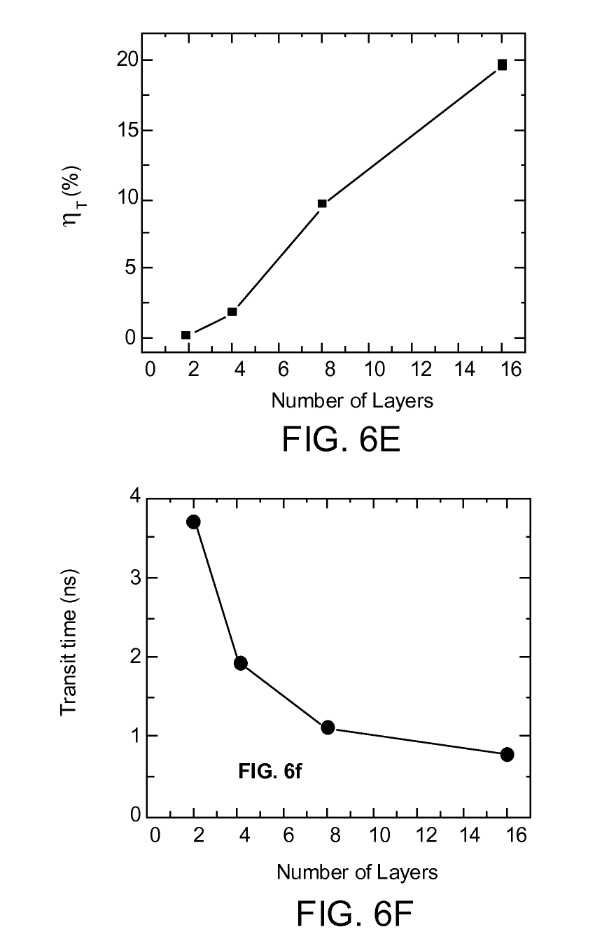

To further inspect super-diffusion in these multiple interface systems, an example histogram of final exciton location for each of the structures is presented in FIGS. 6A-D. Exciton gating occurred on the more concentrated side of each permeable interface. FIG. 6A shows the results of simulating of the position of exciton decay for excitons launched from the left side of the device, and migrating toward the right side of the device. In this simulation, the donor layer contains a single asymmetric gating interface. The presence of the interface is indicated here for simulation purposes by a change in diffusion length (LD) across the interface. Practically, this is similar to what is encountered for a change of concentration across the interface. FIG. 6B shows the results of a similar simulation as in FIG. 6A, except now there are four donor layers with three permeable gating interfaces. This is again reflected as a staircase type variation in L_{D}. Practically, this is similar to what is encountered for a monotonic change of concentration across the interfaces. FIG. 6C shows the results of a similar simulation as in FIGS. 6A-B, except now there are eight donor layers with seven permeable gating interfaces. This is again reflected as a staircase type variation in L_{D}. FIG. 6D shows the results of a similar simulation as in FIGS. 6A-C, except now there are sixteen donor layers with fifteen permeable gating interfaces. The variation in L_{D} is now effectively continuous as the layer thickness are approaching the molecular size. As such, FIG. 6D shows a near continuous variation in L_{D}. Practically, this is similar to what is encountered for a continuous change of concentration across the interfaces.

As the number of permeable interfaces increased, the relative difference in exciton density between adjacent bins decreased. This may have been due to smaller imbalances in energy transfer rates across the interface since the changes in concentration occur in finer steps as more interfaces are added. In the 16-layer system, where the rates changed continuously, there was a constant increase in exciton number density across the system. Coupled to the deeper penetration of excitons into this system was a concomitant increase in the η_{T} (e.g., as shown in FIG. 6E), which is defined as the probability that an exciton, injected into the most dilute layer, traverses the entire 16-nm-thick structure. Indeed, in this example implementation, nearly 20% of excitons injected into bin 1 were able to traverse the 16 nm layer structure in the 16-layer system even though the average L_{D} was only ˜6 nm. Furthermore, these excitons were collected on a dramatically shorter time scale with the majority being transported below their natural exciton lifetime of T=1 ns (e.g., as shown in FIG. 6F, depicting the average transit time for excitons that traverse the entire structure shown in FIG. 5A and contribute to η_{T} as a function of the number of interfaces). Beyond designing systems for optimal exciton collection, exciton permeable interfaces could also be designed to confine or redistribute excitons faster than could normally be achieved with purely diffusive motion.

From the multiple example implementations presented above, it is clear that exciton permeable interfaces can play an impactful role in determining exciton transport in planar heterojunction OPVs. In fact, developing a better understanding of the phenomena that drive imbalance in energy transfer may serve to shift the paradigm from one that simply optimizes diffusion by enhancing L_{D} or circumvents diffusion via the BHJ to one that deeply considers the properties of exciton permeable interfaces.

In the case of the energy-cascade OPVs modeled based on the donor pairing of SubPc and SubNc, variations in the energy-gap are able to increase the η_{D} for both constituent layers. Such a configuration is favorable in terms of exciton transport since the variation in energy-gap provides the ultimate exciton gate, as energy transfer back to the wider gap donor has a near-zero probability. A similar energetic asymmetry could also be realized using inorganic quantum dots (QDs), where the energy gap is tuned based on QD size via quantum confinement. Exciton transport in QD films is also diffusive, or even sub-diffusive owing to energetic disorder. To overcome this limit, layered structures with exciton permeable interfaces could be used to introduce a symmetry breaking imbalance in energy transfer, again achieving directed transport.

Energy cascade structures can, however, have an impact on other device parameters, notably the open-circuit-voltage (V_{OC}) due to the resultant change in the molecular orbital energy landscape. Careful selection and alignment of molecular orbital energy levels allows for this limitation to be overcome, with energy-cascade OPVs having shown remarkable η_{P}. It should be noted that in the case of SubPc and SubNc, significant long-range Förster energy transfer can occur from SubPc to SubNc. While explicitly accounted for the in the simulations presented here, such is not the general case of any donor pairing. Excitons that move via the relatively short-range Dexter-type energy transfer often will only be able to transfer at the permeable interface, thereby reducing the relative η_{D} of the outer layer.

In dilute donor OPVs that incorporate SubPc in a wide energy gap host material, increases in L_{D} only describe part of the overall increase in η_{D}. A significant contribution to the enhanced donor η_{D} can be attributed to the increasing imbalance in energy transfer from the dilute SubPc layer to the neat SubPc layer with dilution (e.g., as shown in FIG. 4C). The dilute donor OPVs modeled in FIG. 4 are reminiscent of the bilayer structures simulated in FIG. 5B albeit with much different L_{D} and degree of imbalance. The similarity, however, suggests that even larger η_{D} could be achieved by incorporating multiple interfaces, moving towards the super-diffusive regime expounded by the continuously varying structure of FIG. 5C. Furthermore, collecting excitons at shorter timescales after photogeneration may reduce the steady state exciton density within the layer(s). Such an instance could be advantageous to circumvent exciton-exciton or exciton-charge quenching pathways, leading to further enhancement in the η_{D} or charge collection efficiency, respectively.

Overall, we have detailed the emergent properties of exciton permeable interfaces and their effect on the η_{D} in highly efficient OPVs. Combined with enhancements in the bulk L_{D}, the further utilization of exciton permeable interfaces has the ability to fully revitalize interest in the planar heterojunction architecture for next generation OPVs. More broadly, this work demonstrates the utility of exciton permeable interfaces for directing exciton motion, and, in particular, the ability to move excitons to a desired location quickly (in less than the natural lifetime). The ability to overcome the diffusive limit is expected to impact the design of a broad range of organic optoelectronic devices where excitons play a mediating role in the conversion of light to charge and vice-versa.

The implementations described above can be implemented using a variety of techniques. Illustrative examples are described below.

### Stochastic Simulations:

Kinetic Monte Carlo modeling was used to generate simulations for the exciton density profiles η_{EQE}, η_{A} and η_{D}. Energy transfer rates for the bulk can were derived from a simple, nearest-neighbor interpretation of the exciton diffusivity, D=LD²τ⁻¹=d² k, where d is the discretization of the KMC model, or bin spacing, and k is the energy transfer rate input. Estimates for the molecular densities of each material were obtained from crystallographic information when available and from powder densities otherwise. The exciton generation rate, Q(x) were simulated using transfer matrix formalism of the incident optical field. The optical constants of each material were measured by variable angle spectroscopic ellipsometry. For the simulations of OPV devices, the MoOₓ anode buffer layer were approximated as a reflecting boundary.

### Device Fabrication:

Organic photovoltaic cells were fabricated on glass slides coated with a 150-nm-thick layer of indium-tin-oxide (ITO) having a sheet resistance of 15Ω/□. All substrates were cleaned with tergitol and solvents. Additionally, ITO substrates were exposed to a UV-ozone ambient for 10 minutes prior to the deposition of the active layers. Organic layers were deposited via vacuum thermal sublimation (<10⁻⁷ Torr) at a nominal rate of 0.2 nm/s. Devices were capped with a 100-nm-thick cathode layer of Al deposited at a nominal rate of 0.3 nm/s through a shadow mask defining an active area with a diameter of 1 mm. Layer thicknesses were initially optimized via transfer matrix simulations of the internal optical field.

### Optoelectronic Characterization:

External quantum efficiency testing was performed under illumination from a 300 W Xenon lamp coupled to a Cornerstone 130 ⅛ meter monochromator and chopped with a Stanford Research Systems SR540 optical chopper. Electrical characteristics can be measured using a Stanford Research Systems SR810 lock-in amplifier. Devices were also characterized under AM 1.5 G solar radiation, and the parameters can be extracted from current-voltage testing at an illumination of (100±5) mW/cm².

### Supplementary Information:

### Artificial Energy Cascade Device Simulation

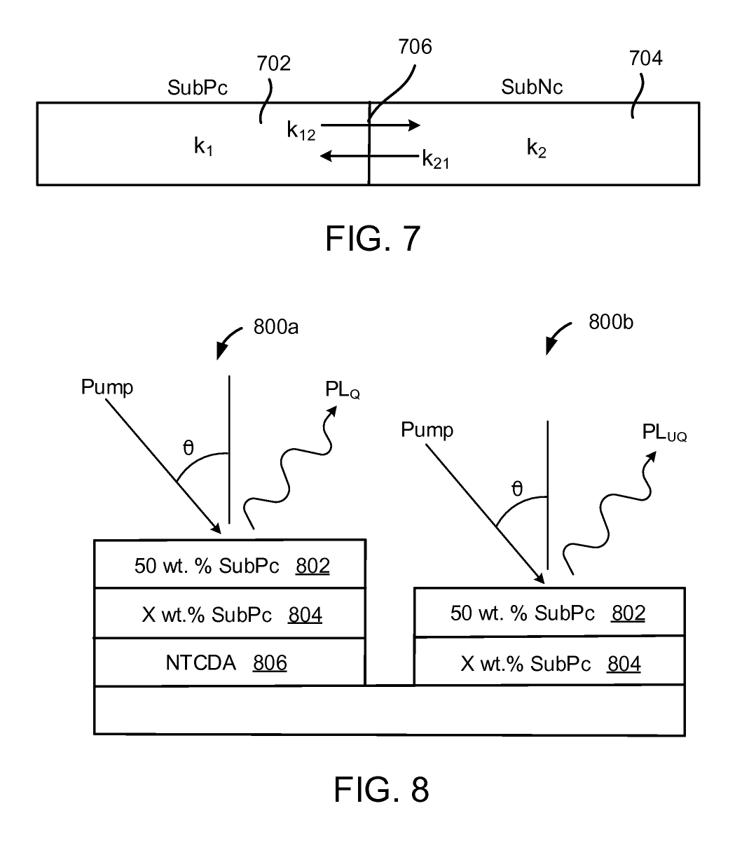

In some implementations, the following strategy was employed to emulate an artificial energy-cascade organic photovoltaic cell (OPV) where no imbalance in energy transfer is present at the exciton permeable interface. In the actual energy cascade OPV (e.g., as shown in FIG. 3A) based on the sequential donor layers of boron subphthalocyanine chloride (SubPc) and boron subnaphthalocyanine chloride (SubNc), the variation in energy-gap created an imbalance in energy transfer. The energy transfer from SubPc 702 to SubNc 704 at the interface 706 (k₁₂), seen schematically in FIG. 7, was dominated by long range Förster energy transfer with a characteristic Förster Radius (R₀) tabulated to be R_{0,12}=2.1 nm. Since R_{0,21}˜0 nm, no energy transfer from SubNc to SubPc is allowed, creating directed exciton transport towards the dissociating interface. The bulk rates for SubPc (k₁) and SubNc (k₂) were determined from the diffusion lengths (L_{D}) and exciton lifetimes (τ). While τ₁ for SubPc was measured, τ₂ for SubNc was taken to be 1 ns for the purposes of these simulations and did not affect the results. The hopping rates for each discretized location within the layer were determined from the simple approximation, L_{D}²=d² k, where d is the discretization and k is the tabulated hopping rate, as summarized in Table 1.

In some cases, to simulate the artificial device, there must be no imbalance in energy transfer at the interface and the bulk L_{D} for each layer must remain the same for both SubPc and SubNc. First, τ₂ was adjusted to τ₂=0.94 ns. As such, the bulk hopping rates were identical for each layer, but the L_{D} for each layer remained unique. Second, R_{0,12} was set to R_{0,12}=0 nm to ensure that there is no long range energy transfer occurring across the permeable interface. Both these considerations ensured the artificial device retains the bulk diffusive behavior of the real device while not incorporating the additional effects of the interfacial exciton gate created by the energy-gap variation at the permeable interface.

TABLE 1
Hopping rate comparison for the real and artificial energy-cascade OPVs

| | | | | | R_{0,12} | | | | |
|---|---|---|---|---|---|---|---|---|---|
| Device | k₁ (ns⁻¹) | k₂ (ns⁻¹) | k₁₂ (ns⁻¹) | k₂₁ (ns⁻¹) | (nm) | τ₁ (ns) | τ₂ (ns) | L_{D,1} (nm) | L_{d,2} (nm) |
| Real | 238 | 225 | 238 | 0 | 2.1 | 0.48 | 1 | 10.7 | 15 |
| Artificial | 238 | 238 | 238 | 238 | 0 | 0.48 | 0.94 | 10.7 | 15 |

### Concentration Dependence of Interlayer in Dilute Donor Films

Photoluminescence (PL) quenching experiments were performed in order to confirm the optimum SubPc concentration for interlayer between the dilute donor and acceptor in a dilute donor OPV. To perform these measurements, the layer structures 800a and 810b found in FIG. 8 were each be fabricated with a dilute donor region that included of a 20-nm-thick layer of 50 wt. % boron subphthalocyanine chloride (SubPc) dispersed in p-bis(triphenylsilyl)benzene (UGH2) 802. The interlayer 804 included a 10-nm-thick layer of SubPc dispersed in UGH2 of variable concentration. A 10-nm-thick layer of 1,4,5,8-naphthalene-tetracarboxylic-dianhydride (NTCDA) 806 (as shown structure 810b) was utilized as a quenching layer due to its favorable energy level alignment with SubPc and wide energy gap. A PL ratio was then defined as the measured PL of the quenched structure (PL_{Q}) (structure 800a) divided by the measured PL of the unquenched structure (PL_{UQ}) (structure 810b).

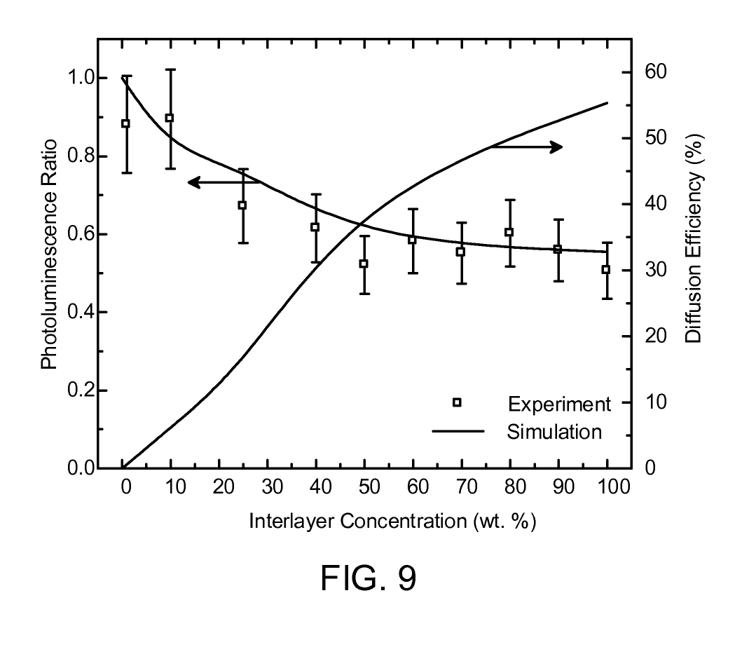

In order to fit the measured PL ratios, a Kinetic Monte Carlo (KMC) algorithm were used to solve the 1-D exciton diffusion equation. A transfer matrix formalism was used to determine the optical field and rate of exciton generation within the structure. Hopping rates within each layer were determined from measured values of L_{D} as a function of concentration. The imbalance in energy transfer at the interfaces were captured by explicitly including the effects of both the imbalance in molecular site density and intermolecular separation. Care was taken to include the effect of a variable PL efficiency between the layers. The KMC modeling also allowed for the tabulation of the exciton diffusion efficiency (η_{D}) as a function of interlayer concentration. Example results of these measurements and corresponding simulations are found in FIG. 9.

In an example implementation, good agreement was found between the measured and predicted PL ratios for all interlayer concentrations explored in this work. It was determined that the smallest PL ratios and largest η_{D} occur when then interlayer is most concentrated and includes a pure layer of SubPc, despite the fact that SubPc has a smaller exciton diffusion length (L_{D}) than a majority of the other interlayer concentrations explored. This behavior can be rationalized only by considering the effects of the exciton permeable interface formed between the two donor layers.

It can be shown that the largest imbalances in energy transfer are achieved when the interlayer is most concentrated. Such a situation maximizes the difference in molecular site density and direct exciton transport towards the quenching interface. Such behavior confirms the selection of a neat SubPc donor layer nearest the donor-acceptor interface in dilute donor OPVs.

In general, this application discloses the use of exciton permeable interfaces that act as gates for excitons. These interfaces act as gates, as by design, the rates of forward and reverse exciton energy transfer are not equal. As such, the exciton may be funneled preferential in one direction. In implementations of the organic photovoltaic cells discussed above, excitons are funneled toward the dissociating interface for photoconversion. Implementations of these devices thus overcome the often undesired randomness of a normal diffusive process, in which the exciton has probability to hop away from the dissociating interface. In some implementations, the required asymmetry in transfer rates can be realized by engineering film composition. For example, an interface can be designed with a neat layer of donor material (SubPc) on the right side of the interface and a dilute layer of donor material (SubPc in UGH2) on the left side of the interface. As discussed above, the asymmetry here arises primarily from a difference in the number of available sites for hopping on either side of the interface as well as the distance to these sites. However, some implementations of this concept may not be limited to the use of a single interface. In some cases, multiple interfaces can be used, either in a donor region (e.g., adjacent one or more layers of donor material), in an acceptor region (e.g., adjacent to one or more layers of acceptance material), or in both donor and acceptor regions. For example, FIGS. 6A-F show that additional gains in exciton harvesting (e.g., as shown in FIG. 6E) are expected as additional gating interfaces are included. As such, a series of gating interfaces can be placed in series or, a continuous variation in energy transfer rates can be implemented (e.g., via a composition gradient) to realize a greater effect biasing of exciton motion and enhanced harvesting.

A number of embodiments of the invention have been described. Nevertheless, it will be understood that various modifications may be made without departing from the spirit and scope of the invention. Accordingly, other embodiments are within the scope of the following claims.

What is claimed is:

1. An organic photovoltaic device comprising:
an organic electron donor region; and
an organic electron acceptor region, wherein the acceptor region forms a donor-acceptor interface with the donor region; and
wherein at least one of the donor region and the acceptor region comprises an exciton permeable interface, wherein an energy transfer imbalance across the exciton permeable interface is configured to bias exciton transfer towards the donor-acceptor interface.

2. The organic photovoltaic device of claim 1, wherein the energy transfer imbalance is due to a difference in concentration of a first material across the exciton permeable interface.

3. The organic photovoltaic device of claim 2, wherein at least one of the donor region and the acceptor region comprises:
a first organic layer comprising a first concentration of the first material; and
a second organic layer comprising a second concentration of the first material,
wherein the first organic layer is disposed between the second organic layer and the donor-acceptor interface,
wherein the first concentration is greater than the second concentration, and
wherein the exciton permeable interface is an interface between the first organic layer and the second organic layer.

4. The organic photovoltaic device of claim 3, wherein the first concentration is 100%.

5. The organic photovoltaic device of claim 3, wherein the first concentration is less than 100%.

6. The organic photovoltaic device of claim 1, wherein the energy transfer imbalance is due to a difference in molecular ordering across the exciton permeable interface.

7. The organic photovoltaic device of claim 1, wherein the energy transfer imbalance is due to a difference in photoluminescence efficiency across the exciton permeable interface.

8. The organic photovoltaic device of claim 1, wherein the energy transfer imbalance is due to a difference in index of refraction across the exciton permeable interface.

9. The organic photovoltaic device of claim 1, wherein the energy transfer imbalance is due to a difference in molecular orbital energy levels across the exciton permeable interface.

10. The organic photovoltaic device of claim 1, wherein the energy transfer imbalance is due to a difference in spectral overlap integral across the exciton permeable interface.

11. The organic photovoltaic device of claim 1, wherein the acceptor region comprises an optically absorbing material.

12. The organic photovoltaic device of claim 1, wherein at least one of the donor region and the acceptor region further comprises a plurality of exciton permeable interfaces, wherein an energy transfer imbalance across each exciton permeable interface is configured to bias exciton transfer towards the donor-acceptor interface.

13. The organic photovoltaic device of claim 12, wherein at least one of the donor region and the acceptor layer further comprises a plurality of organic layers, wherein each exciton permeable interface is an interface between adjacent organic layers.

14. The organic photovoltaic device of claim 13, wherein an energy transfer imbalance across the plurality of layers is configured to bias exciton transfer towards the donor-acceptor interface.

15. The organic photovoltaic device of claim 13, where each organic layer has a respective concentration of a material such that the material concentration varies monotonically across the plurality of organic layers.

16. The organic photovoltaic device of claim 13, where each organic layer has a respective concentration of a material such that the material concentration varies continuously across the plurality of organic layers.

17. The organic photovoltaic device of claim 13, wherein at least one organic layer has a respective concentration of material that varies across that organic layer.

18. The organic photovoltaic device of claim 1, further comprising:
one or more additional organic electron donor regions and one or more additional organic acceptor region, wherein the additional electron donor regions and additional acceptor regions form one or more additional donor-acceptor interfaces,
wherein at least one of the additional donor regions and acceptor regions comprises an additional exciton permeable interface, wherein an energy transfer imbalance across the additional exciton permeable interface is configured to bias exciton transfer towards at least one of the additional donor-acceptor interfaces.

19. The organic photovoltaic device of claim 1, wherein the energy transfer imbalance is due to a difference in exciton radiative decay rate across the exciton permeable interface.
